(19) United States
(12) Patent Application Publication
(10) Pub. No.: US 2017/0330785 A1
(43) Pub. Date: Nov. 16, 2017

(54) SHEET, TAPE, AND METHOD FOR MANUFACTURING SEMICONDUCTOR DEVICE

(71) Applicant: Nitto Denko Corporation, Osaka (JP)

(72) Inventors: Ryuichi KIMURA, Osaka (JP); Naohide TAKAMOTO, Osaka (JP)

(21) Appl. No.: 15/588,996

(22) Filed: May 8, 2017

(30) Foreign Application Priority Data
May 10, 2016 (JP) 2016-094499

(51) Int. Cl. H01L 21/683

(52) U.S. Cl. CPC H01L 21/6836

(57) ABSTRACT

[PROBLEM] In accordance with one aspect of the present invention, to provide a tape and a sheet that make it possible to reduce cracking that would otherwise occur at the chip side face during dicing.

[SOLUTION MEANS] One aspect of the present invention relates to a sheet. The sheet comprises dicing film. The dicing film comprises a base layer and an adhesive layer disposed on the base layer. The sheet further comprises a semiconductor backside protective film disposed on the adhesive layer. Shear adhesive strength at 25° C. of the semiconductor backside protective film with respect to a silicon chip is not less than 1.7 kgf/mm².

### TECHNICAL FIELD

The present invention relates to a sheet, a tape, and a method for manufacturing a semiconductor device.

### BACKGROUND ART

Where semiconductor backside protective film with integral dicing film is employed, there are situations in which semiconductor wafer(s) and semiconductor backside protective film disposed on dicing film are laminated together and dicing is carried out.

### PRIOR ART REFERENCES

### Patent References

PATENT REFERENCE NO. 1: Japanese Patent Application Publication Kokai No. 2015-222896
PATENT REFERENCE NO. 2: WO2014/092200

### SUMMARY OF INVENTION

### Problem to be Solved by Invention

Cracking may occur at the chip side face due to impact and friction occurring during dicing with a dicing saw. It is necessary to reduce chip side face cracking, i.e., sidewall chipping. This is because cracking detracts from outward appearance, and there is a possibility that it could impair reliability.

It is an object of one aspect of the present invention to provide a tape and a sheet that make it possible to reduce cracking that would otherwise occur at the chip side face during dicing. It is an object of one aspect of the present invention to provide a method for manufacturing a semiconductor device.

### Means for Solving Problem

One aspect of the present invention relates to a sheet. The sheet comprises dicing film. The dicing film comprises a base layer and an adhesive layer disposed on the base layer. The sheet further comprises a semiconductor backside protective film disposed on the adhesive layer. Shear adhesive strength at 25° C. of the semiconductor backside protective film with respect to a silicon chip is not less than 1.7 kgf/mm². Because shear adhesive strength at 25° C. is not less than 1.7 kgf/mm², it is possible to reduce cracking that would otherwise occur at the chip side face during dicing. It is speculated that suppression of vibration of semiconductor chip(s) during dicing is made possible. Shear adhesive strength at 25° C. may be measured by securing the semiconductor backside protective film to a silicon chip at 70° C., heating this for 2 hours at 120° C., and thereafter carrying out measurement at 25° C. and shear rate 500 μm/sec.

One aspect of the present invention relates to a tape. The tape comprises a release liner and a sheet disposed on the release liner.

One aspect of the present invention relates to a semiconductor device manufacturing method. The semiconductor device manufacturing method may comprise an operation in which a semiconductor wafer and the semiconductor backside protective film of the sheet are laminated together. The semiconductor device manufacturing method may comprise an operation in which the semiconductor backside protective film is cured. The semiconductor device manufacturing method may comprise an operation in which the semiconductor wafer disposed on the post-curing semiconductor backside protective film is subjected to dicing.

### BRIEF DESCRIPTION OF DRAWINGS

FIG. 1 Schematic plan view of a tape.

FIG. 2 Schematic sectional diagram of a portion of a tape.

FIG. 3 Schematic sectional diagram showing an operation for manufacturing a semiconductor device.

FIG. 4 Schematic sectional diagram showing an operation for manufacturing a semiconductor device.

FIG. 5 Schematic sectional diagram showing an operation for manufacturing a semiconductor device.

FIG. 6 Schematic sectional diagram showing the sheet of Variation 3.

FIG. 7 Schematic sectional diagram of a sheet and a wafer secured to the sheet, showing depth to which a dicing blade cuts thereinto.

FIG. 8 A side view of a post-dicing chip, showing crack depth.

### EMBODIMENTS FOR CARRYING OUT INVENTION

Although the present invention is described in detail below in terms of embodiments, it should be understood that the present invention is not limited only to these embodiments.

### Embodiment 1

As shown in FIG. 1, tape 1 comprises release liner 13 and sheets 71a, 71b, 71c, . . . 71m (hereinafter collectively referred to as “sheets 71”) disposed on release liner 13. Tape 1 may be in the form of a roll. The distance between sheet 71a and sheet 71b, the distance between sheet 71b and sheet 71c, . . . and the distance between sheet 711 and sheet 71m, is constant.

Release liner 13 is in the form of a tape. Release liner 13 might, for example, be polyethylene terephthalate (PET) film.

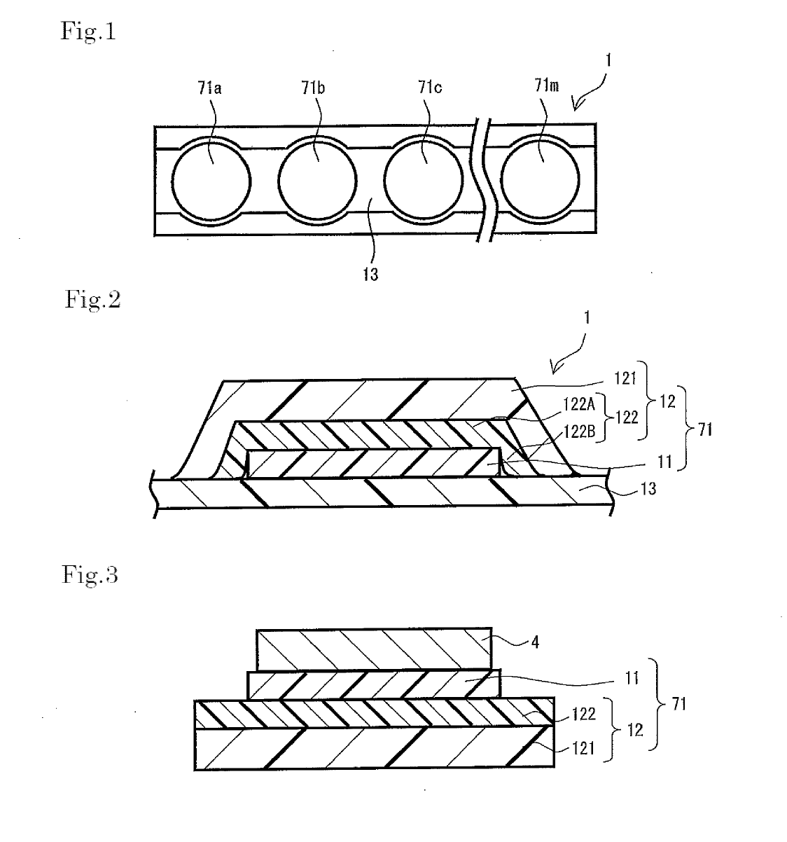

As shown in FIG. 2, sheet 71 comprises dicing film 12. Dicing film 12 is disc-shaped. Dicing film 12 comprises base layer 121 and adhesive layer 122 disposed on base layer 121. Base layer 121 is disc-shaped. The two faces of base layer 121 may be defined such that there is a first principal plane and a second principal plane opposite the first principal plane. The first principal plane of base layer 121 is in contact with adhesive layer 122. Thickness of base 121 might, for example, be 50 μm to 150 μm. It is preferred that base layer 121 have a property permitting an energy beam to be transmitted therethrough. Adhesive layer 122 is disc-shaped. The two faces of adhesive layer 122 may be defined such that there is a first principal plane and a second principal plane opposite the first principal plane. The first principal plane of adhesive layer 122 is in contact with semiconductor backside protective film 11. The second principal plane of adhesive layer 122 is in contact with base layer 121. It is preferred that thickness of adhesive layer 122 be not less than 3 μm, and more preferred that this be not less than 5 μm. It is preferred that thickness of adhesive layer 122 be not greater than 50 μm, and more preferred that this be not greater than 30 μm. The adhesive which makes up adhesive layer 122 might, for example, be acrylic adhesive and/or rubber-type adhesive. Of these, acrylic adhesive is preferred. The acrylic adhesive might, for example, be an acrylic adhesive in which the base polymer thereof is an acrylic polymer (homopolymer or copolymer) employing one, two, or more varieties of (meth)acrylic acid alkyl ester as monomer component(s).

Adhesive layer 122 may comprise first portion 122A. The first portion may be disc-shaped. First portion 122A is in contact with semiconductor backside protective film 11. First portion 122A is harder than second portion 122B. First portion 122A may, for example, be cured by means of an energy beam. Adhesive layer 122 may further comprise second portion 122B arranged peripherally with respect to first portion 122A. Second portion 122B may be in the shape of a flattened donut. Second portion 122B may have a property permitting it to be cured by means of an energy beam. As energy beam, ultraviolet beams and the like may be cited as examples. Second portion 122B is not in contact with semiconductor backside protective film 11.

Sheet 71 comprises semiconductor backside protective film 11. Semiconductor backside protective film 11 is disc-shaped. The two faces of semiconductor backside protective film 11 may be defined such that there is a first principal plane and a second principal plane opposite the first principal plane. The first principal plane of semiconductor backside protective film 11 is in contact with release liner 13. The second principal plane of semiconductor backside protective film 11 is in contact with adhesive layer 122.

It is preferred that thickness of semiconductor backside protective film 11 be not less than 2 μm, more preferred that this be not less than 4 μm, still more preferred that this be not less than 6 μm, and particularly preferred that this be not less than 10 μm. It is preferred that thickness of semiconductor backside protective film 11 be not greater than 200 μm, more preferred that this be not greater than 160 μm, still more preferred that this be not greater than 100 μm, and particularly preferred that this be not greater than 80 μm.

The shear adhesive strength at 25° C. of semiconductor backside protective film 11 with respect to a silicon chip is not less than 1.7 kgf/mm². Because shear adhesive strength at 25° C. is not less than 1.7 kgf/mm², it is possible to reduce cracking that would otherwise occur at the chip side face during dicing. It is speculated that suppression of vibration of semiconductor chip(s) during dicing is made possible. The lower limit of the range in values for the shear adhesive strength at 25° C. may, for example, be 1.8 kgf/mm². The upper limit of the range in values for the shear adhesive strength at 25° C. may, for example, be 4 kgf/mm², 3.5 kgf/mm², 3 kgf/mm², or the like. The shear adhesive strength at 25° C. may be adjusted by adjusting the ratio of thermoplastic resin to thermosetting resin or the like. Shear adhesive strength at 25° C. may be measured by securing semiconductor backside protective film 11 to a silicon chip at 70° C., heating this for 2 hours at 120° C., and thereafter carrying out measurement at 25° C. and shear rate 500 μm/sec. More specifically, shear adhesive strength at 25° C. may be measured by the methods described in the Working Examples.

It is preferred that the shear adhesive strength at 100° C. of semiconductor backside protective film 11 with respect to a silicon chip be not less than 0.5 kgf/mm². If shear adhesive strength at 100° C. is not less than 0.5 kgf/mm², this will permit attainment of excellent reliability, as there will tend to be little occurrence of chip debris scattering during dicing and little occurrence of delamination of semiconductor backside protective film 11 during the reflow operation. It is preferred that shear adhesive strength at 100° C. be not less than 1.0 kgf/mm², and more preferred that this be not less than 2.0 kgf/mm².

Semiconductor backside protective film 11 is colored. If this is colored, it may be possible to easily distinguish between dicing film 12 and semiconductor backside protective film 11. It is preferred that semiconductor backside protective film 11 be black, blue, red, or some other deep color. It is particularly preferred that this be black. The reason for this is that this will facilitate visual recognition of laser mark(s).

The deep color means a dark color having L* that is defined in the L*a*b* color system of basically 60 or less (0 to 60), preferably 50 or less (0 to 50) and more preferably 40 or less (0 to 40).

The black color means a blackish color having L* that is defined in the L*a*b* color system of basically 35 or less (0 to 35), preferably 30 or less (0 to 30) and more preferably 25 or less (0 to 25). In the black color, each of a* and b* that is defined in the L*a*b* color system can be appropriately selected according to the value of L*. For example, both of a* and b* are preferably −10 to 10, more preferably −5 to 5, and especially preferably −3 to 3 (above all, 0 or almost 0).

L*, a*, and b* that are defined in the L*a*b* color system can be obtained by measurement using a colorimeter (tradename: CR-200 manufactured by Konica Minolta Holdings, Inc.). The L*a*b* color system is a color space that is endorsed by Commission Internationale de I′Eclairage (CIE) in 1976, and means a color space that is called a CIE1976 (L*a*b*) color system. The L*a*b* color system is provided in JIS Z 8729 in the Japanese Industrial Standards.

It is preferred that semiconductor backside protective film 11 comprise colorant. Colorant might, for example, be dye(s) and/or pigment(s). Of these, dye(s) are preferred, and black dye(s) are more preferred.

It is preferred that colorant(s) be present in semiconductor backside protective film 11 in an amount that is not less than 0.5 wt %, more preferred that this be not less than 1 wt %, and still more preferred that this be not less than 2 wt %. It is preferred that colorant(s) be present in semiconductor backside protective film 11 in an amount that is not greater than 10 wt %, more preferred that this be not greater than 8 wt %, and still more preferred that this be not greater than 5 wt %.

Semiconductor backside protective film 11 may comprise a resin component. It is preferred that the resin component be present in semiconductor backside protective film 11 in an amount that is not less than 30 wt %, and it is more preferred that this be not less than 40 wt %. It is preferred that the resin component be present in semiconductor backside protective film 11 in an amount that is not greater than 80 wt %, and it is more preferred that this be not greater than 70 wt %.

The resin component may comprise thermoplastic resin and thermosetting resin. The value of the ratio of thermoplastic resin to thermosetting resin might for example be not greater than 1, and it is preferred that this be not greater than 0.8, more preferred that this be not greater than 0.65, still more preferred that this be not greater than 0.6, still more preferred that this be not greater than 0.5, and still more preferred that this be not greater than 0.2. The lower limit of the range in values for the ratio of thermoplastic resin to thermosetting resin might, for example, be 0.1, 0.15, or the like. Here, the ratio of thermoplastic resin to thermosetting resin is the wt % ratio of thermoplastic resin content to thermosetting resin content.

As thermoplastic resin, natural rubber; butyl rubber; isoprene rubber; chloroprene rubber; ethylene-vinyl acetate copolymer; ethylene-acrylic acid copolymer; ethylene-acrylic acid ester copolymer; polybutadiene resin; polycarbonate resin; thermoplastic polyimide resin; nylon 6, nylon 6,6, and other such polyamide resins; phenoxy resin; acrylic resin; PET (polyethylene terephthalate), PBT (polybutylene terephthalate), and other such saturated polyester resins; polyamide-imide resin; fluorocarbon resin; and the like may be cited as examples. Any one of these thermoplastic resins may be used alone, or two or more species chosen from thereamong may be used in combination. Of these, acrylic resin is preferred.

As thermosetting resin, epoxy resin, phenolic resin, amino resin, unsaturated polyester resin, polyurethane resin, silicone resin, thermosetting polyimide resin, and so forth may be cited as examples. Any one of these thermosetting resins may be used alone, or two or more species chosen from thereamong may be used in combination. As thermosetting resin, epoxy resin having low content of ionic impurities and/or other substances causing corrosion of semiconductor chips is particularly preferred. Furthermore, as curing agent for epoxy resin, phenolic resin may be preferably employed.

The epoxy resin is not especially limited, and examples thereof include bifunctional epoxy resins and polyfunctional epoxy resins such as a bisphenol A type epoxy resin, a bisphenol F type epoxy resin, a bisphenol S type epoxy resin, a brominated bisphenol A type epoxy resin, a hydrogenated bisphenol A type epoxy resin, a bisphenol AF type epoxy resin, a bisphenyl type epoxy resin, a naphthalene type epoxy resin, a fluorene type epoxy resin, a phenol novolak type epoxy resin, an ortho-cresol novolak type epoxy resin, a trishydroxyphenylmethane type epoxy resin, and a tetraphenylolethane type epoxy resin, a hydantoin type epoxy resin, a trisglycidylisocyanurate type epoxy resin, and a glycidylamine type epoxy resin.

Semiconductor backside protective film 11 may comprise an epoxy resin that is liquid at 25° C. and an epoxy resin that is solid at 25° C. This will permit attainment of excellent manufacturability. The value of the ratio of liquid epoxy resin to solid epoxy resin might for example be not less than 0.4, and it is preferred that this be not less than 0.6, more preferred that this be not less than 0.8, and still more preferred that this be not less than 1.0. Here, the ratio of liquid epoxy resin to solid epoxy resin is the wt % ratio of liquid epoxy resin content to solid epoxy resin content.

The phenolic resin acts as a curing agent for the epoxy resin, and examples thereof include novolak type phenolic resins such as a phenol novolak resin, a phenol aralkyl resin, a cresol novolak resin, a tert-butylphenol novolak resin, and a nonylphenol novolak resin, a resol type phenolic resin, and polyoxystyrenes such as polyparaoxystyrene. The phenolic resins can be used alone or two types or more can be used together. Among these phenolic resins, a phenol novolak resin and a phenol aralkyl resin are especially preferable because connection reliability in a semiconductor device can be improved.

The phenolic resin is suitably compounded in the epoxy resin so that a hydroxyl group in the phenolic resin to 1 equivalent of an epoxy group in the epoxy resin component becomes 0.5 to 2.0 equivalents. The ratio is more preferably 0.8 to 1.2 equivalents.

Semiconductor backside protective film 11 may comprise curing accelerator catalyst. For example, this might be amine-type curing accelerator, phosphorous-type curing accelerator, imidazole-type curing accelerator, boron-type curing accelerator, phosphorous-/boron-type curing accelerator, and/or the like.

To cause semiconductor backside protective film 11 to undergo crosslinking to a certain extent in advance, it is preferred that polyfunctional compound(s) that react with functional group(s) and/or the like at end(s) of polymer molecule chain(s) be added as crosslinking agent at the time of fabrication thereof. This will make it possible to improve adhesion characteristics at high temperatures and to achieve improvements in heat-resistance.

Semiconductor backside protective film 11 may comprise filler. Inorganic filler is preferred. This inorganic filler might, for example, be silica, clay, gypsum, calcium carbonate, barium sulfate, alumina, beryllium oxide, silicon carbide, silicon nitride, aluminum, copper, silver, gold, nickel, chromium, lead, tin, zinc, palladium, solder, and/or the like. Any one of these fillers may be used alone, or two or more species chosen from thereamong may be used in combination. Of these, silica is preferred, and fused silica is particularly preferred. It is preferred that average particle diameter of inorganic filler be within the range 0.1 μm to 80 μm. Average particle diameter of inorganic filler might, for example, be measured using a laser-diffraction-type particle size distribution measuring device.

It is preferred that filler be present in semiconductor backside protective film 11 in an amount that is not less than 10 wt %, more preferred that this be not less than 20 wt %, and still more preferred that this be not less than 30 wt %. It is preferred that filler be present in semiconductor backside protective film 11 in an amount that is not greater than 70 wt %, and it is more preferred that this be not greater than 60 wt %, and it is still more preferred that this be not greater than 50 wt %.

Semiconductor backside protective film 11 may comprise other additive(s) as appropriate. As other additive(s), flame retardant, silane coupling agent, ion trapping agent, expander, antioxidizer, antioxidant, surface active agent, and so forth may be cited as examples.

Sheet 71 may be used to manufacture a semiconductor device.

As shown in FIG. 3, sheet 71 and semiconductor wafer 4 are laminated together. More specifically, a roller is used to compression-bond sheet 71 onto semiconductor wafer 4 at 50° C. to 100° C. The two faces of semiconductor wafer 4 may be defined such that there is a circuit side and a backside (also referred to as non-circuit side or non-electrode-forming side) opposite the circuit side. Semiconductor wafer 4 might, for example, be a silicon wafer.

Application of heat to semiconductor backside protective film 11 causes curing of semiconductor backside protective film 11. For example, a heater may be directed at dicing film 12 to cause semiconductor backside protective film 11 to be heated by heat which is made to pass through dicing film 12. Heating might for example be carried out at not less than 120° C., and it is preferred that this be not less than 150° C., more preferred that this be not less than 160° C., and still more preferred that this be not less than 170° C. The upper limit of the range in values thereof might, for example, be 270° C., 260° C., or the like.

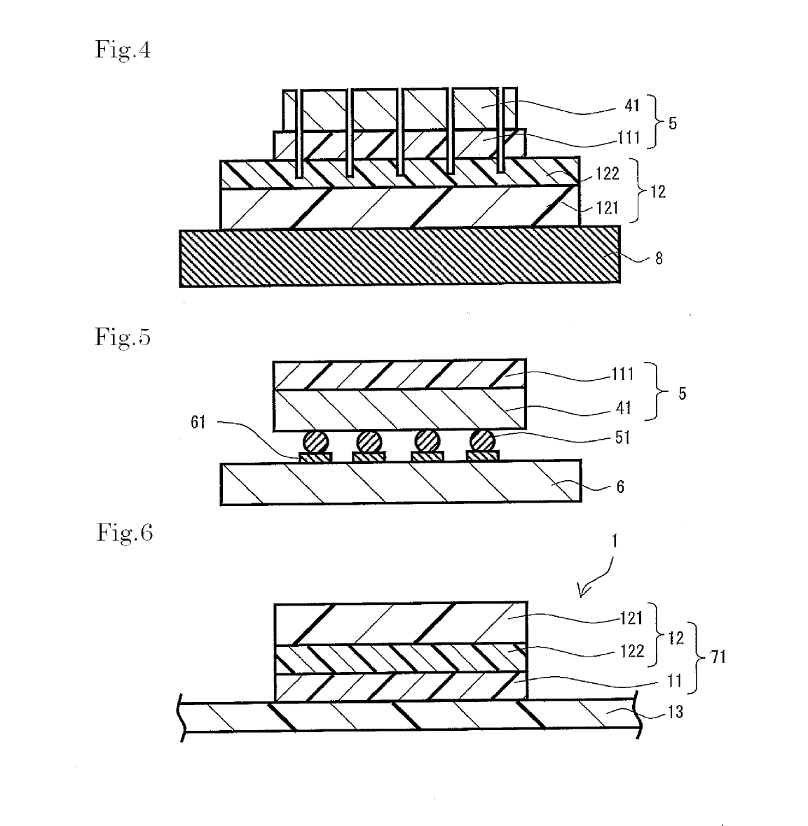

As shown in FIG. 4, dicing film 12 is secured to suction plate 8, and semiconductor wafer 4 is cut to form pre-bonding chips 5. That is, pre-bonding chips 5 are formed as a result of dicing of semiconductor wafer 4. Pre-bonding chip 5 comprises semiconductor chip 41 and post-dicing semiconductor backside protective film 111 disposed on semiconductor chip 41. The two faces of semiconductor chip 41 may be defined such that there is a circuit side and a side (backside) opposite the circuit side.

Needle(s) are used to push up pre-bonding chip 5, and pre-bonding chip 5 is detached from dicing film 12.

As shown in FIG. 5, the flip-chip bonding technique (flip-chip mounting technique) is employed to cause pre-bonding chip 5 to be secured to object 6 to be bonded. More specifically, pre-bonding chip 5 is secured to object 6 to be bonded in such fashion that the circuit side of semiconductor chip 41 is opposed to object 6 to be bonded. For example, bump 51 of semiconductor chip 41 might be made to come in contact with electrically conductive material (solder or the like) 61 of object 6 to be bonded, and while pushing this thereagainst, electrically conductive material 61 might be made to melt. There is a gap between pre-bonding chip 5 and object 6 to be bonded. Height of this gap might typically be on the order of 30 μm to 300 μm. Following securing of constituent parts, it is possible to carry out cleaning of the gap and so forth.

As object 6 to be bonded, a lead frame, circuit board (wiring circuit board), or other such substrate may be employed. As material for such substrate, while there is no particular limitation with respect thereto, ceramic substrate and plastic substrate may be cited as examples. As plastic substrate, epoxy substrate, bismaleimide triazine substrate, polyimide substrate, and the like may be cited as examples.

As material for the bump and/or electrically conductive material, there is no particular limitation with respect thereto, it being possible to cite examples that include tin-lead-type metallic materials, tin-silver-type metallic materials, tin-silver-copper-type metallic materials, tin-zinc-type metallic materials, tin-zinc-bismuth-type metallic materials, and other such solders (alloys); gold-type metallic materials; and copper-type metallic materials. Note that temperature at the time of melting of electrically conductive material 61 might ordinarily be on the order of 260° C. If post-dicing semiconductor backside protective film 111 comprises epoxy resin, it will be able to withstand such temperatures.

The gap between pre-bonding chip 5 and object 6 to be bonded is sealed with resin sealant. Resin sealant might ordinarily be cured by heating for 60 seconds to 90 seconds at 175° C.

As resin sealant, so long as it is a resin that has insulating characteristics (insulating resin), there is no particular limitation with respect thereto. As resin sealant, it is more preferred that this be an insulating resin that has elasticity. As resin sealant, resin compositions comprising epoxy resins and the like may be cited as examples. Furthermore, as resin sealant which is a resin composition comprising epoxy resin, the resin component thereof may, besides epoxy resin, comprise thermosetting resin other than epoxy resin (phenolic resin and/or the like), thermoplastic resin, and/or the like. Where phenolic resin is employed, note that this may also serve as curing agent for epoxy resin. Resin sealant may take the form of sheet(s), tablet(s), and/or the like.

A semiconductor device (flip-chip-mounted semiconductor device) obtained in accordance with the foregoing method comprises object 6 to be bonded, semiconductor chip 41 secured to object 6 to be bonded, and post-dicing semiconductor backside protective film 111 disposed on semiconductor chip 41.

A laser may be used to carry out marking of post-dicing semiconductor backside protective film 111 of the semiconductor device. Note that known laser marking apparatuses may be employed when carrying out laser marking. Furthermore, as laser, gas lasers, solid-state lasers, liquid lasers, and the like may be employed. More specifically, as gas laser, while there is no particular limitation with respect thereto and any known gas laser may be employed, carbon dioxide gas lasers (CO₂ lasers) and excimer lasers (ArF lasers, KrF lasers, XeCl lasers, XeF lasers, etc.) are preferred. Furthermore, as solid-state laser, while there is no particular limitation with respect thereto and any known solid-state laser may be employed, YAG lasers (Nd:YAG lasers, etc.) and YVO₄ lasers are preferred.

A semiconductor device in which semiconductor elements are mounted in a flip chip bonding manner is thinner and smaller than a semiconductor device in which semiconductor elements are mounted in a die bonding manner. For this reason, the former semiconductor device is appropriately usable for various electric instruments or electronic components, or as a component or member of these instruments or components. Specifically, an electronic instrument in which the flip-chip-bonded semiconductor device is used is, for example, the so-called “portable telephone” or “PHS”, a small-sized computer (such as the so-called “PDA” (portable data assistant), the so-called “laptop computer”, the so-called “net book (trademark)”, or the so-called “wearable computer”), a small-sized electronic instrument to which a “portable telephone” and a computer are integrated, the so-called “digital camera (trademark)”, the so-called “digital video camera”, a small-sized television, a small-sized game machine, a small-sized digital audio player, the so-called “electronic notebook”, the so-called “electronic dictionary”, the so-called electronic instrument terminal for “electronic dictionary”, a small-sized digital-type clock, or any other mobile type electronic instrument (portable electronic instrument). Of course, the electronic instrument may be, for example, an electronic instrument of a type (setup type) other than any mobile type (this instrument being, for example, the so-called “disk top computer”, a thin-type television, an electronic instrument for recording and reproduction (such as a hard disk recorder or a DVD player), a projector, or a micro machine). An electronic component in which the flip-chip-bonded semiconductor device is used, or such a component or member of an electronic instrument or electronic component is, for example, a member of the so-called “CPU”, or a member of a memorizing unit (such as the so-called “memory”, or a hard disk) that may be of various types.

### Variation 1

First portion 122A of adhesive layer 122 has a property permitting it to be cured by means of an energy beam. Second portion 122B of adhesive layer 122 also has a property permitting it to be cured by means of an energy beam. At Variation 1, following the operation in which pre-bonding chip 5 is formed, adhesive layer 122 is irradiated with an energy beam and pick-up of pre-bonding chip 5 is carried out. Irradiating this with an energy beam facilitates pick-up of pre-bonding chip 5.

### Variation 2

First portion 122A of adhesive layer 122 is cured by means of an energy beam. Second portion 122B of adhesive layer 122 is also cured by means of an energy beam.

### Variation 3

As shown in FIG. 6, the entire surface of one side of adhesive layer 122 is in contact with semiconductor backside protective film 11.

### MISCELLANEOUS

Any of Variation 1 through Variation 3 and/or the like may be combined as desired.

As described above, a method for manufacturing a semiconductor device associated with Embodiment 1 comprises an operation in which in which semiconductor wafer 4 and semiconductor backside protective film 11 of sheet 71 are laminated together; an operation in which semiconductor backside protective film 11 is cured; and an operation in which semiconductor wafer 4 disposed on cured semiconductor backside protective film 11 is subjected to dicing. The manufacturing method may further comprise an operation in which pick-up of pre-bonding chip 5 formed at the operation in which semiconductor wafer 4 is subjected to dicing is carried out. The manufacturing method may further comprise an operation in which pre-bonding chip 5 is secured to object 6 to be bonded.

### Working Examples

Below, exemplary detailed description of this invention is given in terms of preferred working examples. Note, however, that except where otherwise described as limiting, the materials, blended amounts, and so forth described in these working examples are not intended to limit the scope of the present invention thereto.

### Fabrication of Semiconductor Backside Protective Film at Working Example 1

For every 100 parts by weight of the solids content—i.e., solids content exclusive of solvent—of acrylic acid ester copolymer (SG-70L; manufactured by Nagase ChemteX Corporation), 20 parts by weight of epoxy resin (jER YL980; manufactured by Mitsubishi Chemical Corporation), 50 parts by weight of epoxy resin (KI-3000; manufactured by Tohto Chemical Industry Co., Ltd.), 75 parts by weight of phenolic resin (MEH7851-SS; manufactured by Meiwa Plastic Industries, Ltd.), 180 parts by weight of spherical silica (SO-25R; average particle diameter 0.5 μm; manufactured by Admatechs Company Limited), 10 parts by weight of dye (OIL BLACK BS; manufactured by Orient Chemical Industries Co., Ltd.), and 20 parts by weight of catalyst (2PHZ; manufactured by Shikoku Chemicals Corporation) were dissolved in methyl ethyl ketone to prepare a resin composition solution having a solids concentration of 23.6 wt %. The resin composition solution was applied to a release liner (Diafoil MRA50; Mitsubishi Plastics, Inc. (polyethylene terephthalate film of thickness 50 μm which had been subjected to silicone mold release treatment)). This was dried for 2 minutes at 130° C. to fabricate semiconductor backside protective film having an average thickness of 20 μm.

### Fabrication of Sheet at Working Example 1

A hand roller was used to laminate semiconductor backside protective film to dicing film (V-8-AR; manufactured by Nitto Denko Corporation; dicing film having a base layer of average thickness 65 μm and an adhesive layer of average thickness 10 μm) to obtain a sheet in accordance with Working Example 1. The sheet in accordance with Working Example 1 had dicing film and had semiconductor backside protective film disposed on the adhesive layer of the dicing film.

### Fabrication of Semiconductor Backside Protective Film at Working Example 2

For every 100 parts by weight of the solids content—i.e., solids content exclusive of solvent—of acrylic acid ester copolymer (SG-70L; manufactured by Nagase ChemteX Corporation), 140 parts by weight of epoxy resin (jER YL980; manufactured by Mitsubishi Chemical Corporation), 140 parts by weight of epoxy resin (KI-3000; manufactured by Tohto Chemical Industry Co., Ltd.), 290 parts by weight of phenolic resin (MEH7851-SS; manufactured by Meiwa Plastic Industries, Ltd.), 470 parts by weight of spherical silica (SO-25R; average particle diameter 0.5 μm; manufactured by Admatechs Company Limited), 10 parts by weight of dye (OIL BLACK BS; manufactured by Orient Chemical Industries Co., Ltd.), and 20 parts by weight of catalyst (2PHZ; manufactured by Shikoku Chemicals Corporation) were dissolved in methyl ethyl ketone to prepare a resin composition solution having a solids concentration of 23.6 wt %. The resin composition solution was applied to a release liner (Diafoil MRA50; Mitsubishi Plastics, Inc. (polyethylene terephthalate film of thickness 50 μm which had been subjected to silicone mold release treatment)). This was dried for 2 minutes at 130° C. to fabricate semiconductor backside protective film having an average thickness of 20 μm.

### Fabrication of Sheet at Working Example 2

A hand roller was used to laminate semiconductor backside protective film to dicing film (V-8-AR; manufactured by Nitto Denko Corporation) to obtain a sheet in accordance with Working Example 2. The sheet in accordance with Working Example 2 had dicing film and had semiconductor backside protective film disposed on the adhesive layer of the dicing film.

### Fabrication of Semiconductor Backside Protective Film at Comparative Example 1

For every 100 parts by weight of the solids content—i.e., solids content exclusive of solvent—of acrylic acid ester copolymer (SG-70L; manufactured by Nagase ChemteX Corporation), 10 parts by weight of epoxy resin (HP-4700; manufactured by Dainippon Ink And Chemicals, Incorporated), 10 parts by weight of phenolic resin (MEH7851-H; manufactured by Meiwa Plastic Industries, Ltd.), 70 parts by weight of spherical silica (SO-25R; average particle diameter 0.5 μm; manufactured by Admatechs Company Limited), 10 parts by weight of dye (OIL BLACK BS; manufactured by Orient Chemical Industries Co., Ltd.), and 10 parts by weight of catalyst (2PHZ; manufactured by Shikoku Chemicals Corporation) were dissolved in methyl ethyl ketone to prepare a resin composition solution having a solids concentration of 23.6 wt %. The resin composition solution was applied to a release liner (Diafoil MRA50; Mitsubishi Plastics, Inc. (polyethylene terephthalate film of thickness 50 μm which had been subjected to silicone mold release treatment)). This was dried for 2 minutes at 130° C. to fabricate semiconductor backside protective film having an average thickness of 20 μm.

### Fabrication of Sheet at Comparative Example 1

A hand roller was used to laminate semiconductor backside protective film to dicing film (V-8-AR; manufactured by Nitto Denko Corporation) to obtain a sheet in accordance with Comparative Example 1. The sheet in accordance with Comparative Example 1 had dicing film and had semiconductor backside protective film disposed on the adhesive layer of the dicing film.

### Silicon Chip Preparation

A bare wafer manufactured by Tokyo Kakoh Corporation was ground to a thickness of 0.7 mm. Employed as grinding wheels were a GF01-SD320-BT100-50 as Z1, and a BGT-270 IF-01-9-4/6-B-K09 as Z2. A DPW-018 DP-F05 450×11T×60 wheel was employed for surface dry polishing. Following grinding, dicing was carried out to obtain Silicon Chip A which was 3 mm×3 mm×0.7 mm thickness and Silicon Chip B which was 9.5 mm×9.5 mm×0.7 mm thickness.

### Shear Adhesive Strength at 25° C.

Backside protective film was laminated to Silicon Chip A (3 mm×3 mm×0.7 mm thickness) at 70° C., and any excess protruding beyond the backside protective film was cut off. As a result, a structure was obtained which was made up of cut backside protective film, and Silicon Chip A which was in contact with the first plane of the cut backside protective film. Silicon Chip B (9.5 mm×9.5 mm×0.7 mm thickness) at 70° C. was attached to the second plane of the cut backside protective film, and this was heated at 120° C. for 2 hours. As a result, an object was obtained which was made up of Silicon Chip A, Silicon Chip B, and cured backside protective film disposed between Silicon Chip A and Silicon Chip B. A 4000-Series device manufactured by Dage Co. Ltd. was used to apply a load to the side face of Silicon Chip A at 25° C. and shear rate 500 μm/sec and to measure the load required to cause shear delamination to occur between Silicon Chip A and the cured backside protective film. Results are shown in TABLE 1.

### Shear Adhesive Strength at 100° C.

Except for the fact that stage temperature of the 4000-Series device manufactured by Dage Co. Ltd. was set to 100° C. and the fact that the object—the object being made up of Silicon Chip A, Silicon Chip B, and cured backside protective film disposed between Silicon Chip A and Silicon Chip B—on the stage was heated for 1 minute, the same method as at Shear Adhesive Strength at 25° C. was employed to measure shear adhesive strength at 100° C. Results are shown in TABLE 1.

### Chipping

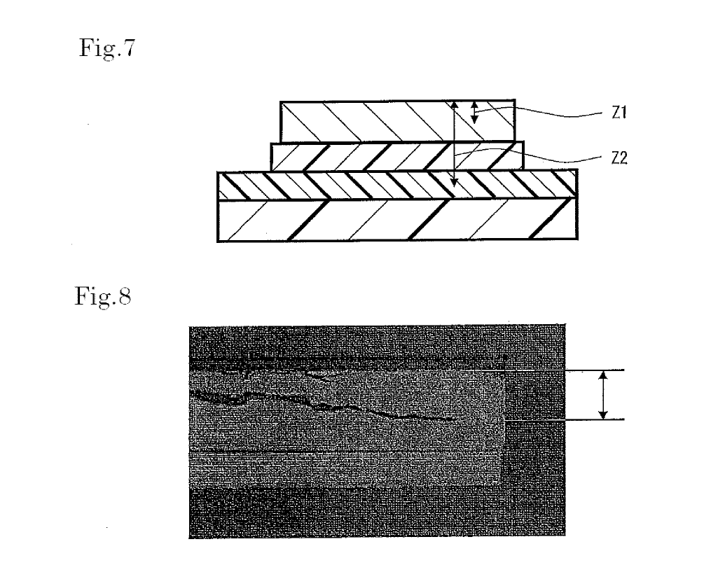

A wafer (silicon mirror wafer of thickness 0.2 mm, diameter 8 inches, the backside of which had been subjected to polishing treatment) was compression-bonded at 70° C. by means of a roller to the semiconductor backside protective film of the sheet. The wafer which was secured to the sheet was subjected to dicing to form pre-bonding chips. The pre-bonding chip had a silicon chip and had a post-dicing semiconductor backside protective film secured to the silicon chip. As shown in FIG. 7, adjustment was carried out so as to obtain a cut depth Z1—depth from the surface of the silicon chip—of 45 μm. Adjustment of cut depth Z2 was carried out so as to obtain a cut depth Z2 that extended into the adhesive layer of the dicing tape by one half-thickness thereof.

### Dicing Conditions

Dicing apparatus: Product name “DFD-6361” manufactured by Disco Corporation

Dicing ring: “2-8-1” (Disco Corporation)

Dicing speed: 30 mm/sec
Dicing blades:
   Z1: “2030-SE 27HCDD” manufactured by Disco Corporation
   Z2: “2030-SE 27HCBB” manufactured by Disco Corporation
Dicing blade rotational speed:
   Z1: 40,000 r/min
   Z2: 45,000 r/min
Cutting method: Step-cut
Chip size: 2.0 mm square

The pre-bonding chips were detached from the dicing film. A microscope (VHX500; manufactured by Keyence Corporation) was used to observe the cut surface of the silicon chip—the surface which of the four cut surfaces was the last to be cut—and the microscope was used to measure crack depth. As shown in FIG. 8, crack depth was the depth from the interface between the semiconductor backside protective film and the silicon chip. Crack depth was evaluated as EXCELLENT if it was less than 10% on a scale for which 100% corresponded to the silicon chip thickness. Crack depth was evaluated as GOOD if it was less than 30%. Crack depth was evaluated as BAD if it was 30% or greater. Results are shown in TABLE 1.

TABLE 1

| | Working | Working | Comparative |
|---|---|---|---|
| | Example 1 | Example 2 | Example 1 |
| Value of ratio of thermoplastic | 0.69 | 0.18 | 5.00 |
| resin to thermosetting resin | | | |
| Value of ratio of liquid epoxy resin | 0.4 | 1.0 | — |
| to solid epoxy resin | | | |

Evaluation

| | | | |
|---|---|---|---|
| Shear adhesive strength at | 1.83 | 2.61 | 1.62 |
| 25° C. kgf/mm² | | | |
| Shear adhesive strength at | 0.28 | 2.14 | 0.29 |
| 100° C. kgf/mm² | | | |
| Chipping | Good | Excellent | Bad |

### EXPLANATION OF REFERENCE NUMERALS

1 Tape
11 Semiconductor backside protective film
12 Dicing film
121 Base layer
122 Adhesive layer
122a First portion
122b Second portion
13 Release liner
71 Sheet
4 Semiconductor wafer
5 Pre-bonding chip
6 Object to be bonded
8 Suction plate
41 Semiconductor chip
51 Bump
61 Electrically conductive material
111 Post-dicing semiconductor backside protective film

1. A sheet comprising:
a dicing film comprising a base layer and an adhesive layer disposed on the base layer; and
a semiconductor backside protective film disposed on the adhesive layer;
wherein the semiconductor backside protective film has a shear adhesive strength at 25° C. with respect to a silicon chip of not less than 1.7 kgf/mm².

2. The sheet according to claim 1 wherein the semiconductor backside protective film comprises thermoplastic resin and thermosetting resin; and
a value of a ratio of the thermoplastic resin to the thermosetting resin is not greater than 1.

3. A tape comprising:
a release liner; and
the sheet according to claim 1 disposed on the release liner.

4. A method for manufacturing a semiconductor device comprising:
an operation in which a semiconductor wafer and the semiconductor backside protective film of the sheet according to claim 1 are laminated together;
an operation in which the semiconductor backside protective film is cured;
an operation in which the semiconductor wafer disposed on the post-curing semiconductor backside protective film is subjected to dicing.
